(19) United States
(12) Patent Application Publication
(10) Pub. No.: US 2007/0096091 A1
(43) Pub. Date: May 3, 2007

(54) LAYER STRUCTURE AND REMOVING METHOD THEREOF AND MEHOD OF TESTING SEMICONDUCTOR MACHINE

(76) Inventor: Chih-Chun Wang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,929

(22) Filed: Nov. 3, 2005

(51) Int. Cl. H01L 23/58; H01L 29/10

(52) U.S. Cl. 257/48

(57) ABSTRACT

A method of testing a semiconductor machine is provided. A wafer is provided and a removable auxiliary layer is formed on the wafer. A low dielectric constant dielectric layer with an expected thickness is formed on the removable auxiliary layer. The actual thickness of the low dielectric constant dielectric layer is measured and then compared with the expected value to determine if the deposition machine operates normally. The low dielectric constant dielectric layer is removed and then the removable auxiliary layer is removed. The method permits a recycling of the test wafer to reduce the production cost.

### BACKGROUND OF THE INVENTION

1. Field of the Invention

The present invention relates to a method of removing film layers. More particularly, the present invention relates to a method of removing a low dielectric constant dielectric layer.

2. Description of the Related Art

In semiconductor fabrication process, a number of chemical vapor deposition processes is currently in use. The plasma-enhanced chemical vapor deposition process is a chemical deposition assisted by heat energy and plasma.

In general, all semiconductor production equipment must be tested daily so as to control the quality of the products produced by the machines. It is essential that the chemical vapor deposition machine produces a film layer with a uniform thickness in each deposition; otherwise, the film quality may be considerably inconsistent. Hence, one major reason for the daily testing of the plasma-enhanced chemical vapor deposition machine is to monitor the deposition of the machine and ensure a stable operation so that deposition of non-uniform or unexpected film layers can be avoided. The method of testing the plasma-enhanced deposition machine includes depositing a layer of low dielectric constant film on a bare silicon wafer, that is, the testing wafer. Then, the properties of the low dielectric constant film such as the particle size, thickness, degree of uniformity and reflectivity are measured and the actual values are compared with the expected values to ensure the machine works in a stable and normal manner.

However, the low dielectric constant film contains a substantial amount of carbon that may react with the wafer. Hence, even diluted hydrofluoric (DHF) acid solution cannot thoroughly remove the entire low dielectric constant film on the wafer that leads to some low dielectric constant film layer residue on the testing wafer. As a result, the testing wafer cannot be reused and the production cost is thus increased.

### SUMMARY OF THE INVENTION

Accordingly, at least one objective of the present invention is to provide a layer structure that permits the recycling of a testing wafer.

At least another objective of the present invention is to provide a method of removing a low dielectric constant dielectric layer such that no residue is left on a testing wafer after the low dielectric constant dielectric layer is removed.

At least another objective of the present invention is to provide a method of testing a semiconductor machine that can reduce the cost consumed on wafer testing.

To achieve these and other advantages and in accordance with the purpose of the invention, as embodied and broadly described herein, the invention provides a layer structure disposed on a wafer suitable for testing a semiconductor machine. The layer structure includes a removable auxiliary layer and a low dielectric constant dielectric layer. The low dielectric constant layer is disposed on the removable auxiliary layer.

According to one embodiment of the present invention, the removable auxiliary layer in the layer structure is a silicon oxide layer fabricated by performing a chemical vapor deposition process using tetraethosiloxane (TEOS) as the reactive gas, for example.

According to one embodiment of the present invention, the chemical vapor deposition process for forming the layer structure is a plasma-enhanced chemical vapor deposition, for example.

According to one embodiment of the present invention, the removable auxiliary layer includes a silicon nitride layer formed by performing a chemical vapor deposition process using silane (SiH₄) as the reactive gas.

According to one embodiment of the present invention, the semiconductor machine is a chemical vapor deposition station, for example.

According to one embodiment of the present invention, the material constituting the low dielectric constant dielectric layer includes silicon carbide, the black diamond material produced by Applied Material Corp. or the coral material produced by Novellus System Corp., for example.

According to one embodiment of the present invention, the wafer is a silicon wafer, for example.

The present invention also provides a method of removing a low dielectric constant dielectric layer suitable for removing a low dielectric constant dielectric layer on a wafer. One major aspect of the removing process includes forming a removable auxiliary layer before forming the low dielectric constant dielectric layer and then removing the low dielectric constant dielectric layer.

According to one embodiment of the present invention, the method of removing the low dielectric constant dielectric layer includes performing a wet etching operation, for example.

According to one embodiment of the present invention, the wet etching operation uses diluted hydrofluoric acid as the etching solution, for example.

The present invention also provides a method of testing a semiconductor machine. First, a wafer is provided. Then, a removable auxiliary layer is formed on the wafer. Then, a low dielectric constant dielectric layer with an expected thickness is formed on the removable auxiliary layer. After that, the actual thickness of the low dielectric constant dielectric layer is measured and then compared with the expected thickness to determine if the deposition machine operates normally. Then, the low dielectric constant dielectric layer is removed. Finally, the removable auxiliary layer is removed.

According to one embodiment of the present invention, the method of removing the low dielectric constant dielectric layer and the removable auxiliary layer includes performing a wet etching operation, for example.

According to one embodiment of the present invention, the wet etching operation uses diluted hydrofluoric acid as the etching solution, for example.

In the present invention, the testing wafer used for testing the machine has a removable auxiliary layer formed over the wafer before forming the low dielectric constant dielectric layer. Since the removable auxiliary layer can assist the removal of the low dielectric constant dielectric layer, no significant amount of residue will remain on the wafer after removing the low dielectric constant dielectric layer. Therefore, the testing wafer can be reused after removing the removable auxiliary layer.

In addition, after removing the low dielectric constant dielectric layer and the removable auxiliary layer, a removable auxiliary layer can be deposited on the used testing wafer and then a low dielectric constant dielectric layer is deposited on the removable auxiliary layer again. Because the low dielectric constant dielectric layer in the second deposition has an actual thickness close to the expected thickness, using the testing wafer repeatedly will not affect the reliability of the machine testing operation; thus the cost consumed on the wafer testing can be reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a layer structure according to one embodiment of the present invention.

FIGS. 2A and 2B are schematic cross-sectional views showing the steps of removing a low dielectric constant dielectric layer according to one embodiment of the present invention.

FIG. 3 is a flowchart showing the steps of testing a semiconductor machine according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIG. 1 is a schematic cross-sectional view of a layer structure according to one embodiment of the present invention. As shown in FIG. 1, a layer structure 110 is disposed on a wafer 100. The wafer 100 is a silicon wafer suitable for testing a semiconductor machine and the semiconductor machine is a machine for performing a chemical vapor deposition process, for example. The layer structure 110 comprises a removable auxiliary layer 112 and a low dielectric constant dielectric layer 114.

The removable auxiliary layer 112 is disposed on the wafer 110. The removable auxiliary layer 112 is a silicon oxide layer formed by performing a chemical vapor deposition process using tetraethosiloxane (TEOS) as the reactive gas or a silicon oxide layer formed by performing a chemical vapor deposition process using silane (SiH₄), for example. The chemical vapor deposition process for forming the removable auxiliary layer 112 includes, for example, a plasma-enhanced chemical vapor deposition process.

The low dielectric constant dielectric layer 114 is disposed on the removable auxiliary layer 112. The low dielectric constant dielectric layer 114 is fabricated using material including silicon carbide, the black diamond material produced by Applied Material Corp. or the coral material produced by Novellus System Corp., for example. The low dielectric constant dielectric layer 114 is formed, for example, by performing a chemical vapor deposition process such as a plasma-enhanced chemical vapor deposition process.

The removable auxiliary layer 112 in the layer structure 110 assists the removal of the low dielectric constant dielectric layer 114 such that no substantial amount of residue is produced after removing the low dielectric constant dielectric layer 114. After removing the removable auxiliary layer 112, the wafer 100 for testing the semiconductor machine can be reused.

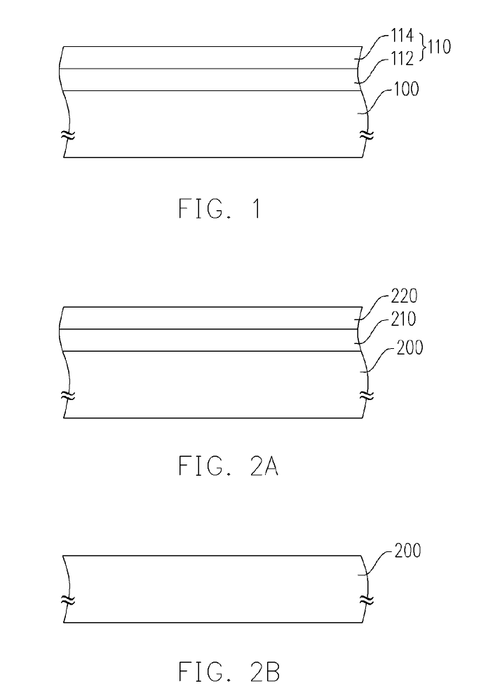

FIGS. 2A and 2B are schematic cross-sectional views showing the steps of removing a low dielectric constant dielectric layer according to one embodiment of the present invention. As shown in FIG. 2A, a wafer 200 such as a silicon wafer is provided. The wafer 200 is suitable for testing a semiconductor machine, for example, a chemical vapor deposition machine. Then, a removable auxiliary layer 210 is formed on the wafer 200. The removable auxiliary layer 210 is a silicon oxide layer formed by performing a chemical vapor deposition process using TEOS gas as the reactive gas or a silicon oxide layer formed by performing a chemical vapor deposition process using silane, for example. The chemical vapor deposition process for forming the removable auxiliary layer 210 includes a plasma-enhanced chemical vapor deposition process, for example.

Next, as shown in FIG. 2A, a low dielectric constant dielectric layer 220 is formed on the removable auxiliary layer 210. The low dielectric constant dielectric layer 220 is fabricated using material including silicon carbide, the black diamond material produced by Applied Material Corp. or the coral material produced by Novellus System Corp., for example. The low dielectric constant dielectric layer 220 is formed, for example, by performing a chemical vapor deposition process such as a plasma-enhanced chemical vapor deposition process.

As shown in FIG. 2B, the low dielectric constant dielectric layer 220 is removed. The method of removing the low dielectric constant dielectric layer 220 includes performing a wet etching operation using diluted hydrofluoric acid as the etching solution, for example.

After removing the low dielectric constant dielectric layer 220, the removable auxiliary layer 210 is also removed. The removable auxiliary layer 210 is removed by performing a wet etching operation using diluted hydrofluoric acid as the etching solution, for example. It should be noted that the removable auxiliary layer could be removed in the same process when removing the low dielectric constant dielectric layer.

Because a removable auxiliary layer 210 is formed between the low dielectric constant dielectric layer 220 and the wafer 200, no significant amount of low dielectric constant dielectric layer residue will remain on the wafer 200 after removing the low dielectric constant dielectric layer 220. Hence, the wafer 200 can be used again to test a semiconductor machine after removing the removable auxiliary layer 210.

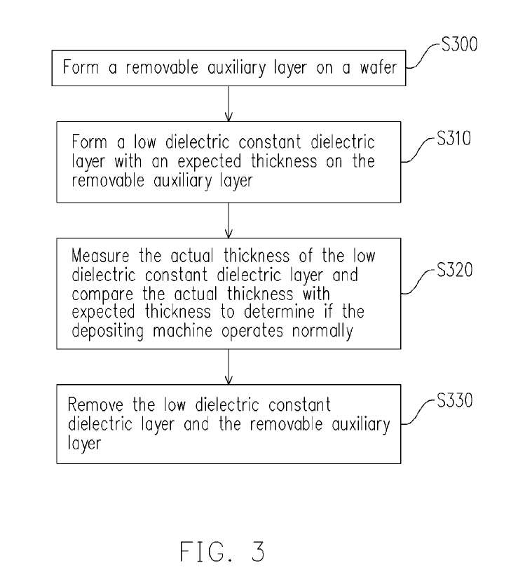

FIG. 3 is a flowchart showing the steps of testing a semiconductor machine according to one embodiment of the present invention.

First, in step S300, a removable auxiliary layer is formed on a wafer.

Then, in step S310, a low dielectric constant dielectric layer with an expected thickness is formed on the removable auxiliary layer.

Next, in step S320, the actual thickness of the low dielectric constant dielectric layer is measured and then the actual thickness is compared with expected thickness to determine if the deposition machine operates normally.

After that, in step S330, the low dielectric constant dielectric layer and the removable auxiliary layer are removed.

Because a removable auxiliary layer is formed between the low dielectric constant dielectric layer and the wafer, no significant amount of low dielectric constant dielectric layer residue will remain on the wafer after removing the low dielectric constant dielectric layer. Hence, the wafer can be used again to test a semiconductor machine after removing the removable auxiliary layer.

Table 4 is a tabulation of the experimental data obtained by testing a semiconductor machine using a conventional method and the method according to the present invention. The experiment can be divided into four groups including a first comparison example, a second comparison example, a first experiment example and a second experiment example. Furthermore, each group of experiment is repeated four times.

The first comparison example is a wafer without depositing any removable auxiliary layer. The experimental method of the first comparison example includes depositing a low dielectric constant dielectric layer having a thickness of about 4700 Å on the wafer. Then, a wet etching operation is performed using diluted hydrofluoric acid solution for about 600 seconds to remove the low K dielectric layer. Next, the thickness and reliability of the residual low dielectric constant (K) dielectric layer after the etching operation are measured. The low K dielectric residue has a thickness exceeding 100 Å and the reliability is around 0.98. After that, another low K dielectric layer having a thickness of about 4700 Å is deposited over the wafer and then the thickness and the reliability are measured. The low K dielectric layer has a thickness of about 4800 Å after the second deposition and the reliability is around 0.98. Since no removable auxiliary layer is formed in the comparison example 1, the low K dielectric layer can easily react with the wafer and hence the low K dielectric layer cannot be completely removed. As a result, the actual thickness of the low K dielectric layer formed in the second deposition process is greater than the expected thickness.

In the second comparison example, the first experiment example and second experiment example, a removable auxiliary layer is formed between the low K dielectric layer and the wafer.

The experimental method of the second comparison example includes forming a silicon oxide layer to serve as a removable auxiliary layer. The method of forming the silicon oxide layer includes performing a chemical vapor deposition process using silane as the reactive gas. Then, a low K dielectric layer having a thickness of about 4700 Å is formed on the removable auxiliary layer. Next, a wet etching operation is performed using diluted hydrofluoric acid solution for about 600 seconds to remove the low K dielectric layer and the removable auxiliary layer. The thickness and reliability of the residue after the etching operation are measured. The residue has a thickness between about 70 Å˜140 Å. However, the reliability is between 0.60˜0.85. This is possibly due to the incomplete removal of the removable auxiliary layer so that the thickness of the residue cannot be accurately measured. Thereafter, another silicon oxide layer to serve as a removable auxiliary layer is formed by performing a chemical vapor deposition process using silane as the reactive gas. After that, another low K dielectric layer having a thickness of about 4700 Å is formed over the wafer. The thickness and reliability of the low K dielectric layer are measured. The low K dielectric constant layer in the second deposition has a thickness between about 4400 Å˜4800 Å. However, the reliability is between about 0.45˜0.75. This is possibly due to the incomplete removal of the removable auxiliary layer so that the measurement is inaccurate.

The experimental method of the first experiment example includes forming a silicon oxide layer to serve as a removable auxiliary layer. The method of forming the silicon oxide layer includes performing a chemical vapor deposition process using tetraethosiloxane (TEOS) as the reactive gas. Then, a low K dielectric layer having a thickness of about 4700 Å is formed on the removable auxiliary layer. Next, a wet etching operation is performed using diluted hydrofluoric acid solution for about 600 seconds to remove the low K dielectric layer and the removable auxiliary layer. The thickness and reliability of the residue after the etching operation are measured. The residue has a thickness lower than 11 Å and a reliability of 0.98. Thereafter, another silicon oxide layer to serve as a removable auxiliary layer is formed by performing a chemical vapor deposition process using tetraethosiloxane (TEOS) as the reactive gas. After that, another low K dielectric layer having a thickness of about 4700 Å is formed over the wafer. The thickness and reliability of the low K dielectric layer are measured. The low K dielectric constant layer in the second deposition has a thickness lower than 4711 Å and a reliability of about 0.98. An additional removable auxiliary layer is formed in the first experiment example so that there is no residue on the wafer after removing the low K dielectric layer and the removable auxiliary layer. Therefore, the actual thickness of the low K dielectric layer in the second deposition approaches the expected thickness.

The experimental method of the second experiment example includes forming a silicon nitride layer to serve as a removable auxiliary layer. The method of forming the silicon nitride layer includes performing a chemical vapor deposition process using silane as the reactive gas. Then, a low K dielectric layer having a thickness of about 4700 Å is formed on the removable auxiliary layer. A wet etching operation is then performed using diluted hydrofluoric acid solution for about 600 seconds to remove the low K dielectric layer and the removable auxiliary layer. The thickness and reliability of the residue after the etching operation are measured. The residue has a thickness lower than 11 Å and a reliability of 0.98. Thereafter, another silicon nitride layer to serve as a removable auxiliary layer is formed by performing a chemical vapor deposition process using silane as the reactive gas. After that, another low K dielectric layer having a thickness of about 4700 Å is formed over the wafer. The thickness and reliability of the low K dielectric layer are measured. The low K dielectric constant layer in the second deposition has a thickness lower than 4711 Å and a reliability of about 0.98. An additional removable auxiliary layer is formed in the first experiment example so that there is no residue on the wafer after removing the low K dielectric layer and the removable auxiliary layer. Therefore, the actual thickness of the low K dielectric layer in the second deposition approaches the expected thickness.

According to the aforesaid experimental examples, the formation of a removable auxiliary layer in the experiment examples 1 and 2 permits the complete removal of the low K dielectric layer and the removable auxiliary layer so that the wafer is completely cleaned without any residue left. Furthermore, the actual thickness of the low K dielectric layer in the second deposition can approach the expected thickness. As seen from the experimental results, the preferred removable auxiliary layer is a silicon oxide layer formed by performing a chemical vapor deposition process using TEOS as the reaction gases and a silicon nitride layer formed by performing a chemical vapor deposition process using silane as the reactive gas.

In summary, the semiconductor machine testing method in the present invention has at least the following advantages.

1. The wafer used for testing the machine has a removable auxiliary layer formed thereon before forming the low K dielectric layer to prevent the formation of a large quantity of low K dielectric layer residues on the wafer. Thus, after removing the removable auxiliary layer, the wafer can be repeatedly used for testing the semiconductor machine.

2. The low K dielectric layer and the removable auxiliary layer of a used testing wafer are removed. Next, a removable auxiliary layer is deposited and then a low K dielectric layer is deposited on the removable auxiliary layer. The actual thickness of the low K dielectric layer in the second deposition approaches the expected thickness. Hence, the testing wafer can be repeatedly used without affecting the reliability of the machine testing operation. Ultimately, less testing wafers are consumed and the production cost can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

TABLE 4
Experimental data for testing a semiconductor machine

| | | | Wet etching with diluted | | After depositing low K | |
|---|---|---|---|---|---|---|
| | | | HF for 600 seconds | | dielectric layer | |
| Experiment | | Wafer | Thickness (Å) | Reliability | Thickness (Å) | Reliability |
| Comparison | Bare wafer + Low K dielectric layer | 1 | 238 | 0.98 | 4921 | 0.98 |
| Example 1 | | 2 | 112 | 0.98 | 4833 | 0.98 |
| | | 3 | 275 | 0.98 | 4971 | 0.98 |
| | | 4 | 392 | 0.98 | 5073 | 0.98 |
| Comparison | Bare wafer + Silicon oxide layer deposited using | 1 | 131 | 0.81 | 4652 | 0.65 |
| Example 2 | silane as reactive gas + Low K dielectric layer | 2 | 89 | 0.79 | 4788 | 0.75 |
| | | 3 | 134 | 0.85 | 4654 | 0.49 |
| | | 4 | 78 | 0.61 | 4431 | 0.67 |
| Experiment | Bare wafer + Silicon oxide layer deposited using | 1 | 11 | 0.98 | 4701 | 0.98 |
| Example 1 | TEOS as reactive gas + Low K dielectric layer | 2 | 6 | 0.98 | 4711 | 0.98 |
| | | 3 | 9 | 0.98 | 4700 | 0.98 |
| | | 4 | 10 | 0.98 | 4700 | 0.98 |
| Experiment | Bare wafer + silicon nitride layer deposited using | 1 | 9 | 0.98 | 4700 | 0.98 |
| Example 2 | silane as reactive gas + Low K dielectric layer | 2 | 7 | 0.98 | 4700 | 0.98 |
| | | 3 | 11 | 0.98 | 4700 | 0.98 |
| | | 4 | 9 | 0.98 | 4700 | 0.98 |

What is claimed is:

1. A layer structure disposed on a wafer suitable for testing a semiconductor machine, the layer structure comprising:
a removable auxiliary layer; and
a low dielectric constant dielectric layer disposed on the removable auxiliary layer.

2. The layer structure of claim 1, wherein the removable auxiliary layer includes a silicon oxide layer formed by performing a chemical vapor deposition process using tetraethosiloxane (TEOS) as the reactive gas.

3. The layer structure of claim 2, wherein the chemical vapor deposition process includes a plasma-enhanced chemical vapor deposition process.

4. The layer structure of claim 1, wherein the removable auxiliary layer includes a silicon nitride layer formed by performing a chemical vapor deposition process using silane (SiH₄) as the reactive gas.

5. The layer structure of claim 1, wherein the semiconductor machine includes a chemical vapor deposition station.

6. The layer structure of claim 1, wherein the material forming the low dielectric constant dielectric layer includes silicon carbide, the black diamond material produced by Applied Material Corp. or the coral material produced by Novellus System Corp.

7. The layer structure of claim 1, wherein the wafer includes a silicon wafer.

8. A method of removing a low dielectric constant dielectric layer suitable for removing the low dielectric constant dielectric layer disposed on a wafer, one major aspect of the method includes forming a removable auxiliary layer on the wafer before forming the low dielectric constant dielectric layer and then removing the low dielectric constant dielectric layer.

9. The method of removing the low dielectric constant dielectric layer of claim 8, wherein the removable auxiliary layer includes a silicon oxide layer formed by performing a chemical vapor deposition process using tetraethosiloxane (TEOS) as the reactive gas.

10. The method of removing the low dielectric constant dielectric layer of claim 9, wherein the chemical vapor deposition process includes a plasma-enhanced chemical vapor deposition process.

11. The method of removing the low dielectric constant dielectric layer of claim 8, wherein the removable auxiliary layer includes a silicon nitride layer formed by performing a chemical vapor deposition process using silane (SiH₄) as the reactive gas.

12. The method of removing the low dielectric constant dielectric layer of claim 8, wherein the step of removing the low dielectric constant dielectric layer includes performing a wet etching operation.

13. The method of removing the low dielectric constant dielectric layer of claim 12, wherein the wet etching operation is carried out using diluted hydrofluoric acid as the etching solution.

14. The method of removing the low dielectric constant dielectric layer of claim 8, wherein the material forming the low dielectric constant dielectric layer includes silicon carbide, the black diamond material produced by Applied Material Corp. or the coral material produced by Novellus System Corp.

15. The method of removing the low dielectric constant dielectric layer of claim 8, wherein the wafer includes a silicon wafer.

16. A method of testing a semiconductor machine, comprising:
providing a wafer;
forming a removable auxiliary layer on the wafer;
forming a low dielectric constant dielectric layer having an expected thickness on the removable auxiliary layer;
measuring an actual thickness of the low dielectric constant dielectric layer;
comparing the actual thickness with the expected thickness to determine if the depositing machine operates normally;
removing the low dielectric constant dielectric layer; and
removing the removable auxiliary layer.

17. The method of testing a semiconductor machine of claim 16, wherein the removable auxiliary layer includes a silicon oxide layer formed by performing a chemical vapor deposition process using tetraethosiloxane (TEOS) as the reactive gas.

18. The method of testing a semiconductor machine of claim 17, wherein the chemical vapor deposition process includes a plasma-enhanced chemical vapor deposition process.

19. The method of testing a semiconductor machine of claim 16, wherein the removable auxiliary layer includes a silicon nitride layer formed by performing a chemical vapor deposition process using silane (SiH₄) as the reactive gas.

20. The method of testing a semiconductor machine of claim 16, wherein the step of removing the low dielectric constant dielectric layer and the removable auxiliary layer includes performing a wet etching operation.

21. The method of testing a semiconductor machine of claim 20, wherein the wet etching operation is carried out using diluted hydrofluoric acid as the etching solution.

22. The method of testing a semiconductor machine of claim 16, wherein the semiconductor machine includes a chemical vapor deposition station.

23. The method of testing a semiconductor machine of claim 16, wherein the material forming the low dielectric constant dielectric layer includes silicon carbide, the black diamond material produced by Applied Material Corp. or the coral material produced by Novellus System Corp.

24. The method of testing a semiconductor machine of claim 16, wherein the wafer includes a silicon wafer.
